(19) United States
(12) Patent Application Publication
(10) Pub. No.: US 2005/0158963 A1
(43) Pub. Date: Jul. 21, 2005

(54) Method of forming planarized shallow trench isolation

(75) Inventors: Darin Chan, San Francisco, CA (US); Simon Siu-Sing Chan, Saratoga, CA (US); Angela Hui, Fremont, CA (US)

Correspondence Address: McDERMOTT, WILL & EMERY, 600 13th Street, N.W., Washington, DC, 20005-3096, US

(73) Assignee: ADVANCED MICRO DEVICES, INC.

(21) Appl. No.: 10/759,207

(22) Filed: Jan. 20, 2004

(51) Int. Cl. H01L 21/76; H01L 21/336

(52) U.S. Cl. 438/424; 438/435; 438/296

(57) ABSTRACT

Planarized STI with minimized topography is formed by selectively etching back the dielectric trench fill with respect to the polish stop film prior to removing the polish stop film. Embodiments include etching back a silicon oxide trench filled to a depth of about 200 Å to about 1,500 Å, and then stripping a silicon nitride polish stop layer leaving a substantially planarized surface, thereby improving the accuracy of subsequent gate electrode patterning and reducing stringers.

### FIELD OF THE INVENTION

The present invention relates to a method of manufacturing semiconductor devices comprising trench isolation. The present invention has particular applicability in manufacturing high density semiconductor devices with submicron design features and active regions isolated by shallow insulated trenches.

### BACKGROUND ART

Current demands for high density and performance associated with ultra large scale integration require a design rule of about 0.12 micron and under, increased transistor and circuit speeds and improved reliability. Such demands for increased density, performance and reliability require formation of device features with high precision and uniformity.

Conventional semiconductor devices comprise a substrate and various electrically isolated regions, called active regions, in which individual circuit components are formed. The electrical isolation of these active regions is typically accomplished by thermal oxidation of the semiconductor substrate, typically monocrystalline silicon or an epitaxial layer formed thereon, bounding the active regions.

One type of isolation structure is known as trench isolation, wherein shallow trenches are etched in the substrate and an oxide liner is thermally grown on the trench walls. The trench is then refilled with an insulation material. The resulting structure is referred to as a shallow trench isolation (STI) structure. The active region typically comprises source/drain regions formed in the semiconductor substrate by implantation of impurities, spaced apart by a channel region on which a gate electrode is formed with a gate oxide layer therebetween. The gate electrode controls the turn-on and turn-off of each transistor.

A typical method of implementing shallow trench isolation comprises initially growing a pad oxide layer on the substrate, and depositing a barrier or polish stop nitride layer thereon. A photoresist mask is then applied to define the trench areas. The exposed portions of the nitride layer are then etched away, followed by etching away the exposed portion of the pad oxide layer. Etching continues into the substrate to form the shallow trench. When etching of the trench is completed, the photoresist is stripped off the nitride layer.

The substrate is then oxidized to form an oxide liner on the walls and base of the trench to control the silicon-silicon dioxide interface quality. The trench is then refilled with an insulating material (or “trench fill”), such as silicon dioxide derived from tetraethyl orthosilicate (TEOS). The surface is then planarized, as by chemical-mechanical polishing (CMP), using the barrier nitride layer as a polish stop layer, and the nitride and pad oxide layer are stripped off the active areas to complete the trench isolation structure.

When creating STI structures, it is considered desirable for the uppermost surface of the substrate containing the shallow trench isolation to be planar with no or minimal topography, for subsequent processing steps, particularly photolithographic processing, thereby facilitating the formation of small features with high accuracy improved reliability and increased manufacturing throughput. However, planarity is adversely affected by conventional techniques, primarily due to the nitride polish stop layer.

Referring to FIGS. 1A-1C, which schematically illustrate the substrate 1, pad oxide layer 2, barrier nitride layer 3, oxide liner 4 and insulating material 5, after insulating material 5 has been applied (FIG. 1A), and planarized using the barrier nitride layer 3 as a polish stop (FIG. 1B). The barrier nitride layer 3 and pad oxide layer 2 are then stripped off (FIG. 1C), creating a step having a height S between the main surface 1a of the substrate 1 and the uppermost surface 5a of the insulating material. Thus, the use of a conventional barrier nitride layer 3 as a polish stop creates a topographical step preventing planarity at the interface of the surface la and the surface 5a. Such a topographical step renders it difficult to photolithographically process subsequent layers of the device, particularly when forming features with fine dimensions, thereby adversely affecting process yield and production cost. This problem becomes more acute as circuit geometry is continuously reduced.

Another problem generated by topographical features, such as the step S schematically illustrated in FIG. 1C, is the formation of polycrystalline stringers. Stringers typically form after patterning a polycrystalline silicon film to form a gate electrode and are schematically illustrated in FIG. 1C by reference numeral 6. Such polycrystalline silicon stringers can disadvantageously result in electrical shorting.

There exists a continuing need for methodology enabling the manufacture of semiconductor devices wherein the uppermost surface of the substrate or epitaxial layer is substantially flush (i.e., coplanar) with the uppermost surface of a STI, thereby facilitating the formation of subsequent layers and enabling photolithographic processing of fine features with greater accuracy and reliability.

### SUMMARY OF THE INVENTION

An object of the present invention is a method of manufacturing a semiconductor device having an insulated trench formed in a semiconductor substrate with improved flatness of the uppermost trench/substrate interface, thereby facilitating formation of subsequent layers, and enabling photolithographic processing of the features for high density devices with greater accuracy and reliability.

Additional objects, advantages and other features of the present invention will be set forth in part in the description which follows and in part will become apparent to those having ordinary skill in the art upon examination of the following or may be learned from the practice of the present invention. The objects and advantages of the present invention may be realized and obtained as particularly pointed out in the appended claims.

According to the present invention, the foregoing and other objects are achieved in part by a method of manufacturing a semiconductor device, the method comprising: forming a pad oxide layer on a main surface of a substrate; forming a polish stop layer on the pad oxide layer; forming an opening in the polish stop layer, pad oxide layer and an opening extending into the substrate; filling the opening in the substrate with a dielectric material forming an overburden on the polish stop layer; planarizing the overburden; etching to remove a portion of the dielectric material forming a step between the dielectric material and polish stop layer; and removing the polish stop layer.

Embodiments of the present invention comprise: forming a pad silicon oxide layer on the main surface of the semiconductor substrate thereon; depositing a silicon nitride polish stop layer on the pad silicon oxide layer; etching to form an opening in the silicon nitride polish stop layer and an opening in the pad silicon oxide layer; etching to form an opening extending into the substrate; implementing chemical vapor deposition to deposit a silicon oxide layer on the polish stop layer filling the opening in the substrate; conducting chemical mechanical polishing such that an upper surface of the silicon oxide layer is substantially coplanar with an upper surface of the silicon nitride polish stop layer; etching to reduce the upper surface of the silicon oxide layer below the upper surface of the silicon nitride polish stop layer; and stripping the silicon nitride polish stop layer.

Embodiments of the present invention comprise etching to reduce the silicon oxide trench fill to create a step between an upper surface of the silicon oxide layer and an upper surface of the silicon nitride polish stop layer of about 200 Å to about 500 Å, e.g., about 500 Å to about 1,000 Å.

Additional objects and advantages of the present invention will become readily apparent to those skilled in this art from the following detailed description, wherein only the preferred embodiment of the present invention is shown and described, simply by way of illustration of the best mode contemplated for carrying out the present invention. As will be realized, the present invention is capable of other and different embodiments, and its several details are capable of modifications in various obvious respects, all without departing from the present invention. Accordingly, the drawings and description are to be regarded as illustrative in nature, and not as restrictive.

### BRIEF DESCRIPTION OF THE DRAWINGS

FIGS. 1A through 1C schematically illustrate sequential phases of a conventional method of STI formation.

FIGS. 2A through 2D schematically illustrate sequential phases of a method in accordance with an embodiment of the present invention.

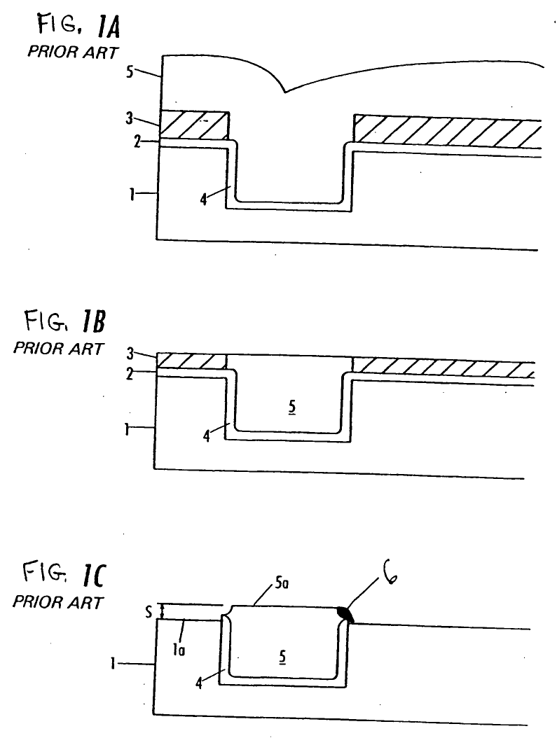

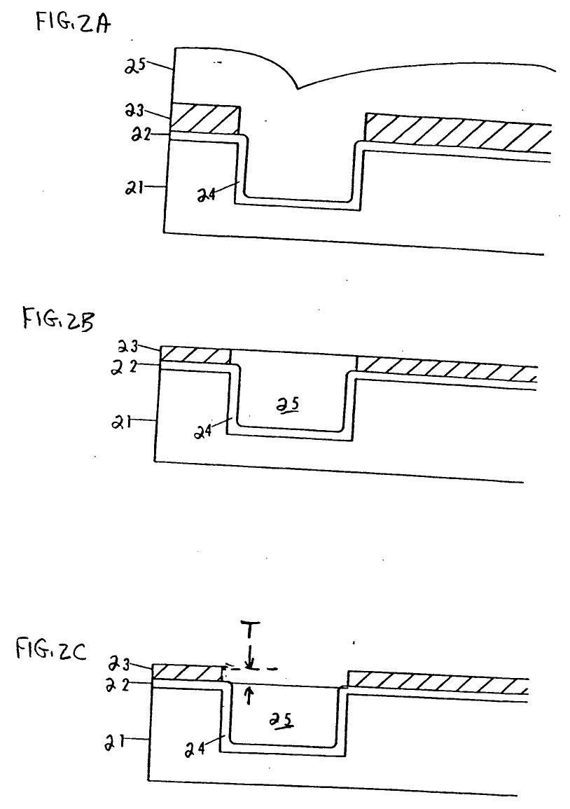

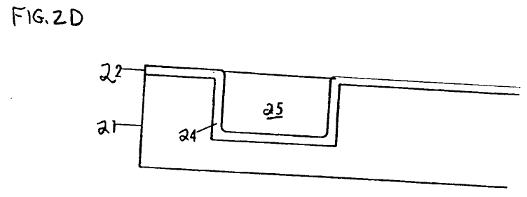

In FIGS. 1A through 1C and in FIGS. 2A through 2D, similar features or elements are denoted by similar reference characters.

### DETAILED DESCRIPTION OF THE INVENTION

The present invention addresses and solves problems stemming from topographical steps attendant upon implementing conventional shallow trench isolation practices. Such topographical steps adversely impact surface planarity and, hence, severely limit the capability of conventional photolithographic techniques in forming features with fine dimensions extending into the deep submicron range. In addition, such topographical steps result in the formation of conductive stringers leading to electrical shorting. The present invention provides methodology enabling the fabrication of semiconductor devices without such undesirable topographical steps at the substrate/trench interface, in a simplified, effective manner.

In accordance with embodiments of the present invention, the trench fill is etched down a distance approximate the thickness of the remaining polish stop layer after CMP, e.g., down to the pad oxide layer. The polish stop layer is then stripped. The resulting trench fill surface is substantially coplanar with the pad oxide surface, thereby avoiding the step S illustrated in FIG. 1C.

Embodiments of the present invention comprise etching the trench fill employing either a wet hydrofluoric acid etch or a dry etch, as by anisotropic etching with CHF₄ and CHF₃ chemistry to reduce the upper surface of the trench fill below the upper surface of polish stop layer forming a step of about 200 Å to about 1,500 Å, e.g., 500 Å to about 1,000 Å. The polish stop layer is then stripped in a conventional manner leaving a substantially planar surface.

An embodiment of the present invention is schematically illustrated in FIGS. 1A through 1D. Adverting to FIGS. 2A and 2D, conventional processing steps are conducted similar to those schematically illustrated in FIGS. 1A through 1B, comprising forming a pad oxide layer 22, e.g., silicon oxide, on an upper surface of substrate 21, and forming a polish stop layer 23, e.g., silicon nitride, on pad oxide layer 22. A photoresist mask (not shown) is then formed on the polish stop layer 23 and an opening is formed in the polish stop layer. An opening is then formed in the pad oxide layer 22. Anisotropic etching is then conducted to form a trench in substrate 1, as at a depth of about 2,500 Å to about 4,000 Å, e.g., about 3,000 Å. Silicon oxide layer 24 is then thermally grown in the trench. CVD is then conducted to deposit silicon oxide layer 25 on polish stop layer 23 and filling the trench. Silicon oxide layer 25 can be deposited in a conventional manner, as by depositing silicon dioxide derived from tetraethyl orthosilicate (TEOS) by low pressure chemical vapor deposition (LPCVD) or silicon dioxide derived from silane by LPCVD. Silicon oxide layer 25 can also comprise a high density plasma oxide. The resulting intermediate structure is schematically illustrated in FIG. 2A.

Adverting to FIG. 2B, planarization is conducted, as by CMP, such that the upper surface of the trench fill 25 is substantially coplanar with the upper surface of silicon nitride polish stop layer 23. The present invention departs from conventional practices by etching the upper surface of trench fill 25 to form a step T illustrated in FIG. 2C, having a height substantially equal to the height of the remaining silicon nitride polish stop layer 23, such as about 200 Å to about 1,500 Å, e.g., 500 Å to about 1,000 Å.

Subsequently, as illustrated in FIG. 2D, the silicon nitride polish stop layer 23 is stripped, as with hot phosphoric acid, leaving a substantially planar surface without the undesirably typographical step S illustrated in FIG. 1C. Processing is then continued in a convention manner, as by depositing a polycrystalline silicon gate electrode layer and patterning to form gate electrodes.

The present invention provides efficient methodology enabling the fabrication of various types of semiconductor devices having STI structures with improved reliability, greater accuracy and reduced electrical shorting. The present invention enjoys industrial utility in fabricating any of various types semiconductor devices, particularly semiconductor devices having STI and a design rule of about 0.12 micron and under.

The present invention can be practiced by employing conventional materials, methodology and equipment. Accordingly, the details of such materials, equipment and methodology are not set forth herein in detail. In the previous descriptions, numerous specific details are set forth, such as specific materials, structures, chemicals, processes, etc., in order to provide a thorough understanding of the present invention. However, the present invention can be practiced without resorting to the details specifically set forth. In other instances, well known processing structures have not been described in detail, in order not to unnecessarily obscure the present invention.

Only the preferred embodiment of the present invention and but a few examples of its versatility are shown and described in the present disclosure. It is to be understood that the present invention is capable of use in various other combinations and environments and is capable of changes or modifications within the scope of the inventive concept as expressed herein.

1. A method of manufacturing a semiconductor device, the method comprising:
forming a pad oxide layer on a main surface of a substrate;
forming a polish stop layer on the pad oxide layer;
forming an opening in the polish stop layer, pad oxide layer and an opening extending into the substrate;
filling the opening in the substrate with a dielectric material forming an overburden on the polish stop layer;
planarizing the overburden;
etching to remove a portion of the dielectric material forming a step between the dielectric material and the polish stop layer; and
removing the polish stop layer.

2. The method according to claim 1, further comprising:
depositing a gate electrode layer; and
patterning the gate electrode layer to form a gate electrode.

3. The method according to claim 1, wherein the polish stop layer comprises silicon nitride.

4. The method according to claim 1, wherein the dielectric layer comprises silicon oxide.

5. The method according to claim 4, comprising depositing the dielectric material by chemical vapor deposition on the polish stop layer filling the opening and forming the overburden.

6. The method according to claim 1, comprising planarizing the overburden by chemical mechanical polishing such that an upper surface of the dielectric material is coplanar with an upper surface of the polish stop layer.

7. The method according to claim 6, comprising etching to form the step of about 200 Å to about 1,500 Å.

8. The method according to claim 7, comprising etching to form the a step of about 500 Å to about 1,000 Å.

9. The method according to claim 1, comprising forming an oxide liner in the opening in the substrate before filling the opening with dielectric material.

10. A method of manufacturing a semiconductor device, the method comprising:
forming a pad oxide layer on a semiconductor substrate;
forming a silicon nitride polish stop layer on the pad oxide layer;
etching to form an opening in the polish stop and pad oxide layers;
etching to form an opening extending into the substrate;
depositing a layer of silicon oxide on the polish stop layer filling the opening in the substrate;
conducting chemical-mechanical polishing such that an upper surface of the silicon oxide layer is substantially coplanar with an upper surface of the polish stop layer;
etching to reduce the upper surface of the silicon oxide layer so that it is below the upper surface of the polish stop layer; and
removing the polish stop layer.

11. The method according to claim 10, comprising forming an oxide liner in the opening in the substrate before depositing the layer of silicon oxide.

12. The method according to claim 10, comprising:
depositing a layer of polycrystalline silicon; and
etching the layer of polycrystalline silicon to form a gate electrode.

13. The method according to claim 10, comprising etching the silicon oxide layer to reduce the upper surface to a distance of about 200 Å to about 1,500 Å below the upper surface of the polish stop layer.

14. The method according to claim 13, comprising etching to reduce the upper surface of the silicon oxide layer to a distance of about 500 Å to about 1,000 Å below the upper surface of the polish stop layer.

15. The method according to claim 10, comprising stripping the silicon nitride polish stop layer by etching under reflux boiling of phosphoric acid at about 180° C.
